(19) United States
(12) Patent Application Publication
(10) Pub. No.: US 2010/0071752 A1
(43) Pub. Date: Mar. 25, 2010

(54) Solar Cell Module Having Buss Adhered With Conductive Adhesive

(75) Inventors: Kim Vellore, San Jose, CA (US); Danny C. Lu, San Francisco, CA (US); Garry Kwong, San Jose, CA (US)

Correspondence Address: DIEHL SERVILLA LLC, 77 BRANT AVENUE, SUITE 210, CLARK, NJ, 07066, US

(73) Assignee: Applied Materials, Inc., Santa Clara, CA (US)

(21) Appl. No.: 12/604,939

(22) Filed: Oct. 23, 2009

(51) Int. Cl. H01L 31/042; H01L 31/18

(52) U.S. Cl. 136/244; 438/66; 257/E21.499

(57) ABSTRACT

Solar cell modules and methods for making solar cell modules are disclosed. In one or more embodiments of the invention, a buss is adhered to the solar cell modules using a plurality of conductive adhesive drops.

### BACKGROUND

1. Field of the Invention

Embodiments of the present invention relate generally to the field of photovoltaic cell manufacturing. More specifically, embodiments of the invention relate to photovoltaic cells and methods for rapidly manufacturing photovoltaic cells using buss wires adhered with a conductive adhesive.

2. Background of the Related Art

Photovoltaic devices or solar cells are devices which convert sunlight into direct current (DC) electrical power. Typical thin film type photovoltaic devices, or thin film solar cells, have one or more p-i-n junctions. Each p-i-n junction comprises a p-type layer, an intrinsic type layer, and an n-type layer. When the p-i-n junction of the solar cell is exposed to sunlight (consisting of energy from photons), the sunlight is converted to electricity through the photovoltaic effect. Solar cells may be tiled into larger solar arrays. The solar arrays are created by connecting a number of solar cells and joining them into panels with specific frames and connectors.

Typically, a thin film solar cell includes active regions, or photoelectric conversion units, and a transparent conductive oxide (TCO) film disposed as a front electrode and/or as a backside electrode. The photoelectric conversion unit includes a p-type silicon layer, an n-type silicon layer, and an intrinsic type (i-type) silicon layer sandwiched between the p-type and n-type silicon layers. Several types of silicon films, including microcrystalline silicon film (p-Si), amorphous silicon film (a-Si), polycrystalline silicon film (poly-Si), and the like, may be utilized to form the p-type, n-type, and/or i-type layers of the photoelectric conversion unit. The backside electrode may contain one or more conductive layers.

With traditional energy source prices on the rise, there is a need for a low cost way of producing electricity using a low cost solar cell device. Conventional solar cell manufacturing processes are highly labor intensive and have numerous interruptions that can affect the production line throughput, solar cell cost, and device yield. For instance, conventional solar cell electrical connection processes require formed electrical leads to be manually positioned and connected to the backside electrode of the solar cell device. These manual processes are labor intensive, time consuming and costly.

The current soldering process uses high temperatures to solder buss wires. The high temperatures can result in delamination and solder marks that are visible on the front surface of the solar cell. Additionally, the high temperatures shortens the lifetime of thermodes, or similar devices, used to solder the buss wires.

The buss wires are frequently soldered to the solar cells using a conductive adhesive. This conductive adhesive is used along the entire strip of the buss wire and requires that a separate curing step, which often occurs during the autoclaving process. Again, the heat required to cure the conductive adhesive can result in delamination of the solar cells.

Additionally, as the size of solar cells increase, such as Generation 8 modules (2.2×2.6 meters modules), the connection of the electrical leads to the solar cell, especially in the center of the solar cell, becomes increasingly difficult for a technician to access and perform.

Therefore, there is a need for photovoltaic modules and methods of rapidly making photovoltaic modules which have a reduced risk of delamination due to head associated with attaching and curing buss wires to the module.

### SUMMARY

One or more embodiments of the invention are directed to solar cell modules comprising at least two solar cells and a buss connecting the at least two solar cells. The buss being adhered to the at least two solar cells by a plurality of conductive adhesive drops.

In specific embodiments, the solar cell comprises a thin film solar panel and the buss comprises a side buss to connect at least two cells for current capture. In other specific embodiments, the solar cell comprises a silicon solar cell and the buss is adhered to at least two solar cells.

In detailed embodiments, the conductive adhesive drops are curable when heated up to a maximum of 300° C. for less than about 7 seconds. In some specific embodiments, substantially no flux or solder is used to connect the side buss to the solar cells.

In detailed embodiments, the plurality of conductive adhesive drops are spaced in the range of about 2 cm to about 4 cm apart. In a specific embodiment, the plurality of conductive adhesive drops are spaced about 3 cm apart. In one or more embodiments, the conductive adhesive drops have a diameter in the range of about 1 mm to about 5 mm.

In some embodiments, the conductive adhesive comprises silver. In detailed embodiments, the conductive adhesive comprises a mixture.

Additional embodiments of the invention are directed to methods of making a solar cell modules. A plurality of conductive adhesive drops are applied to a back contact layer of the solar cell module. Contact points are created by contacting a side buss to the plurality of conductive adhesive drops. The contact points are spot heated to adhere the side buss to the back side of the solar cell module.

In detailed embodiments, the plurality of adhesive drops are spaced in the range of about 2 cm to about 4 cm apart. In some embodiments the contact points are spot heated for up to about 7 seconds. In specific embodiments, the contact points are heated to a temperature up to about 300° C. In detailed embodiments, the contact points are heated by a thermode, ultrasonic, resistive or other electrical heating process.

Further embodiments of the invention are directed to methods of making a solar cell module. A plurality of solar cells are formed. A buss is applied to the plurality of solar cells, the buss connecting a row of solar cells. A buss is applied to the plurality of solar cells, the buss being adhered to the plurality of solar cells by a plurality of conductive adhesive drops.

In detailed embodiments, the conductive adhesive is substantially cured when heated up to 300° C. for up to about 7 seconds. In some detailed embodiments, the buss is adhered to the plurality of solar cells substantially without flux or solder.

### BRIEF DESCRIPTION OF THE DRAWINGS

FIG. 1 illustrates a process sequence for forming a solar cell module according to one or more embodiment of the invention;

FIG. 2A is a side cross-sectional view of a thin film solar cell module according to one or more embodiment of the invention;

FIG. 2B is a side cross-sectional view of a thin film solar cell module according to one or more embodiment of the invention;

FIG. 2C is a plan view of a composite solar cell module according to one or more embodiment of the invention;

FIG. 2D is a side cross-sectional view along Section A-A of FIG. 2C;

FIG. 2E is a side cross-sectional view of a thin film solar cell module according to one or more embodiment of the invention; and

FIG. 2F is an expanded view of a portion of the plan view of a composite solar cell shown in FIG. 2C.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

As used in this specification, the terms “solar cell module” and “solar cell device” (or “device”) have substantially the same meaning, unless clearly indicated by the context of usage. The terms may be used to describe complete solar cell modules, or modules in the process of being made.

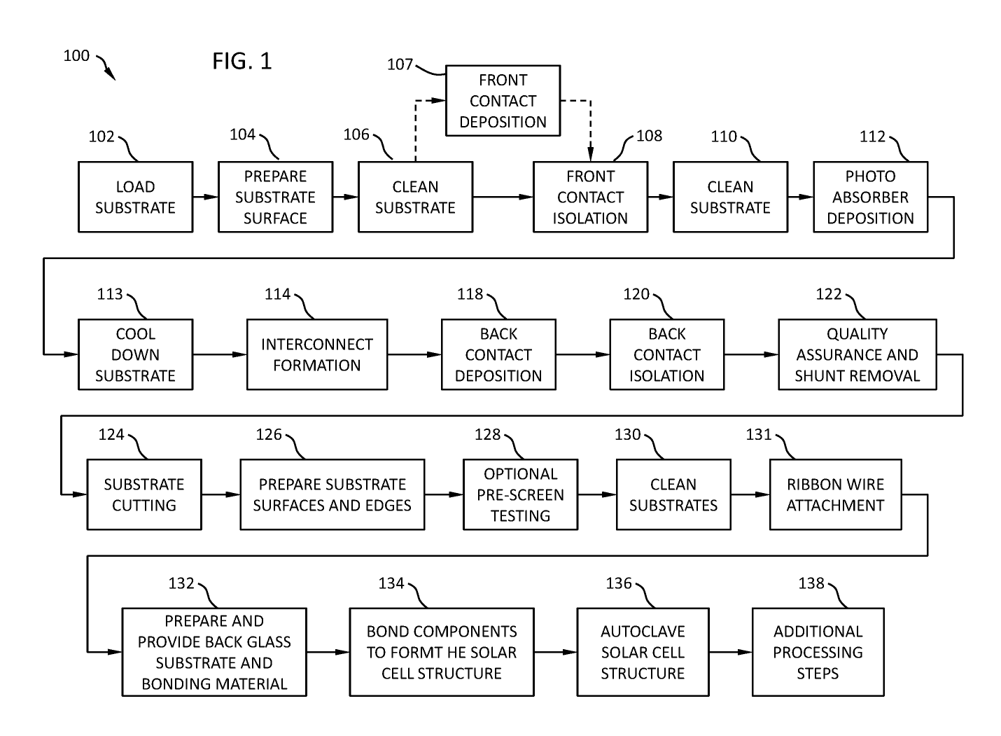

FIG. 1 illustrates a typical process sequence 100 used in the manufacturing of solar cells. It is to be understood that the invention is not limited to the process sequence illustrated in FIG. 1 and described below. Other manufacturing processes can be employed without deviating from the spirit and scope of the invention.

The process sequence 100 generally starts at step 102 in which a substrate is loaded into a loading module. The substrates may be received in a “raw” state where the edges, overall size, and/or cleanliness of the substrates are not well controlled. Receiving “raw” substrates reduces the cost to prepare and store substrates prior to forming a solar module and thus reduces the solar cell module cost, facilities costs, and production costs of the finally formed solar cell module. However, typically, it is advantageous to receive “raw” substrates that have a transparent conducting oxide (TCO) layer already deposited on a surface of the substrate before it is received into the system in step 102. If a conductive layer, such as TCO layer, is not deposited on the surface of the “raw” substrates then a front contact deposition step (step 107), which is discussed below, needs to be performed on a surface of the substrate.

In step 104, the surfaces of the substrate are prepared to prevent yield issues later in the process. The substrate may be inserted into a front end substrate seaming module that is used to prepare the edges of the substrate to reduce the likelihood of damage, such as chipping or particle generation from occurring during the subsequent processes. Damage to the substrate can affect module yield and the cost to produce a usable solar cell module.

Next, the substrate is cleaned (step 106) to remove any contaminants found on the surface. Common contaminants may include materials deposited on the substrate during the substrate forming process (e.g., glass manufacturing process) and/or during shipping or storing of the substrates. Typically, cleaning uses wet chemical scrubbing and rinsing steps to remove any undesirable contaminants, but other cleaning processes can be employed.

In step 108, separate cells are electrically isolated from one another via scribing processes. Contamination particles on the TCO surface and/or on the bare glass surface can interfere with the scribing procedure. In laser scribing, for example, if the laser beam runs across a particle, it may be unable to scribe a continuous line, resulting in a short circuit between cells. In addition, any particulate debris present in the scribed pattern and/or on the TCO of the cells after scribing can cause shunting and non-uniformities between layers.

Prior to performing step 108 the substrate 302 is transported to a front end processing module in which a front contact formation process, or step 107, is performed on the substrate 302. In step 107, the one or more substrate front contact formation steps may include one or more preparation, etching, and/or material deposition steps to form the front contact regions on a bare solar cell substrate 302. Step 107 may comprise one or more PVD steps or CVD steps that are used to form the front contact region on a surface of the substrate 302. The front contact region may contain a transparent conducting oxide (TCO) layer that may contain metal element selected from a group consisting of zinc (Zn), aluminum (Al), indium (In), and tin (Sn). In one example, a zinc oxide (ZnO) is used to form at least a portion of the front contact layer.

Next, the device substrate 303 is transported to the scribe module in which step 108, or a front contact isolation step, is performed on the device substrate 303 to electrically isolate different regions of the device substrate 303 surface from each other. In step 108, material is removed from the device substrate 303 surface by use of a material removal step, such as a laser ablation process. The success criteria for step 108 are to achieve good cell-to-cell and cell-to-edge isolation while minimizing the scribe area.

Next, the device substrate 303 is transported to a cleaning module in which step 110, or a pre-deposition substrate cleaning step, is performed on the device substrate 303 to remove any contaminants found on the surface of the device substrate 303 after performing the cell isolation step (step 108). Typically, cleaning uses wet chemical scrubbing and rinsing steps to remove any undesirable contaminants found on the device substrate 303 surface after performing the cell isolation step.

Next, the device substrate 303 is transported to a processing module in which step 112, which comprises one or more photoabsorber deposition steps, is performed on the device substrate 303. In step 112, the one or more photoabsorber deposition steps may include one or more preparation, etching, and/or material deposition steps that are used to form the various regions of the solar cell device. Step 112 generally comprises a series of sub-processing steps that are used to form one or more p-i-n junctions. In some embodiments, the one or more p-i-n junctions comprise amorphous silicon and/or microcrystalline silicon materials.

A cool down step, or step 113, may be performed after step 112. The cool down step is generally used to stabilize the temperature of the device substrate 303 to assure that the processing conditions seen by each device substrate 303 in the subsequent processing steps are repeatable. Generally, the temperature of the device substrate 303 exiting a processing module can vary by many degrees and exceed a temperature of 50° C., which can cause variability in the subsequent processing steps and solar cell performance.

Next, the device substrate 303 is transported to a scribe module in which step 114, or the interconnect formation step, is performed on the device substrate 303 to electrically isolate various regions of the device substrate 303 surface from each other. In step 114, material is removed from the device substrate 303 surface by use of a material removal step, such as a laser ablation process.

Next, the device substrate 303 may be subjected to one or more substrate back contact formation steps, or step 118. In step 118, the one or more substrate back contact formation steps may include one or more preparation, etching, and/or material deposition steps that are used to form the back contact regions of the solar cell device. Step 118 generally comprises one or more PVD steps or CVD steps that are used to form the back contact layer 350 on the surface of the device substrate 303. In detailed embodiments, the one or more PVD steps are used to form a back contact region that contains a metal layer selected from a group consisting of zinc (Zn), tin (Sn), aluminum (Al), copper (Cu), silver (Ag), nickel (Ni), vanadium (V), molybdenum (Mo), and conductive carbon.

Next, the device substrate 303 is transported to a scribe module in which step 120, or a back contact isolation step, is performed on the device substrate 303 to electrically isolate the plurality of solar cells contained on the substrate surface from each other. In step 120, material is removed from the substrate surface by use of a material removal step, such as a laser ablation process.

Next, the device substrate 303 is transported to a quality assurance module in which step 122, or quality assurance and/or shunt removal steps, are performed on the device substrate 303 to assure that the devices formed on the substrate surface meet a desired quality standard and in some cases correct defects in the formed device. In step 122, a probing device is used to measure the quality and material properties of the formed solar cell device by use of one or more substrate contacting probes.

Next, the device substrate 303 is optionally transported to a substrate sectioning module in which a substrate sectioning step 124 is used to cut the device substrate 303 into a plurality of smaller device substrates 303 to form a plurality of smaller solar cell devices. The device substrate 303 may then be broken along the scored lines to produce the desired size and number of sections needed for the completion of the solar cell devices.

The device substrate 303 is next transported to a seamer/edge deletion module 226 in which a substrate surface and edge preparation step 126 is used to prepare various surfaces of the device substrate 303 to prevent yield issues later on in the process. Damage to the device substrate 303 edge can affect the device yield and the cost to produce a usable solar cell device. The seamer/edge deletion module may be used to remove deposited material from the edge of the device substrate 303 (e.g., 10 mm) to provide a region that can be used to form a reliable seal between the device substrate 303 and the backside glass (i.e., steps 134-136 discussed below). Material removal from the edge of the device substrate 303 may also be useful to prevent electrical shorts in the final formed solar cell.

Next the device substrate 303 is transported to a pre-screen module in which optional pre-screen steps 128 are performed on the device substrate 303 to assure that the devices formed on the substrate surface meet a desired quality standard. In step 128, a light emitting source and probing device may be used to measure the output of the formed solar cell device by use of one or more substrate contacting probes. If the module detects a defect in the formed device it can take corrective actions or the solar cell can be scrapped.

Next the device substrate 303 is transported to a cleaning module in which step 130, or a pre-lamination substrate cleaning step, is performed on the device substrate 303 to remove any contaminants found on the surface of the substrates 303 after performing steps 122-128. Typically, the cleaning uses wet chemical scrubbing and rinsing steps to remove any undesirable contaminants found on the substrate surface after performing the cell isolation step.

Next the substrate 303 is transported to a bonding wire attach module in which a bonding (or ribbon) wire attach step 131 is performed on the substrate 303. Step 131 is used to attach the various wires/leads required to connect various external electrical components to the formed solar cell module 300. The bonding wire attach module may be an automated wire bonding tool that reliably and quickly forms the numerous interconnects required to produce large solar cells 300.

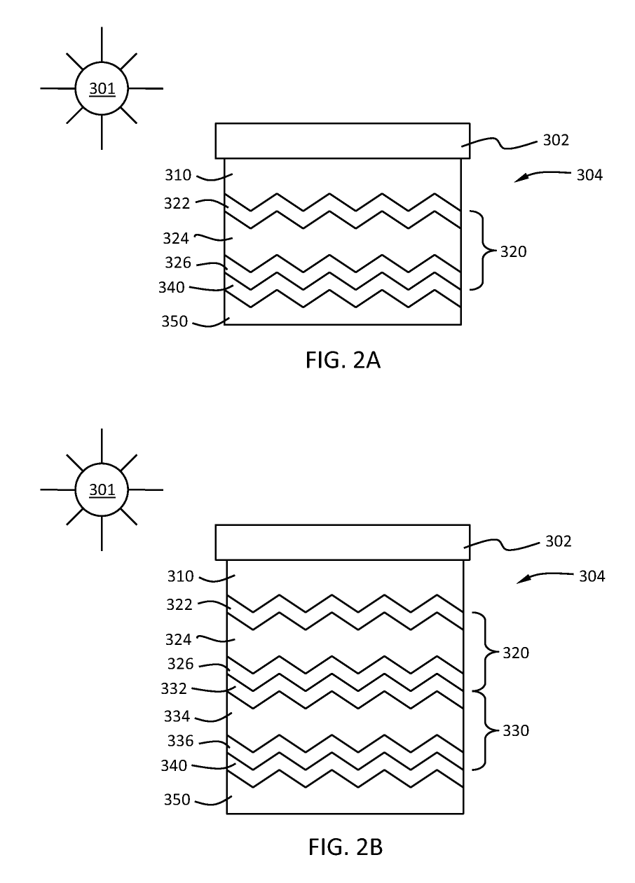

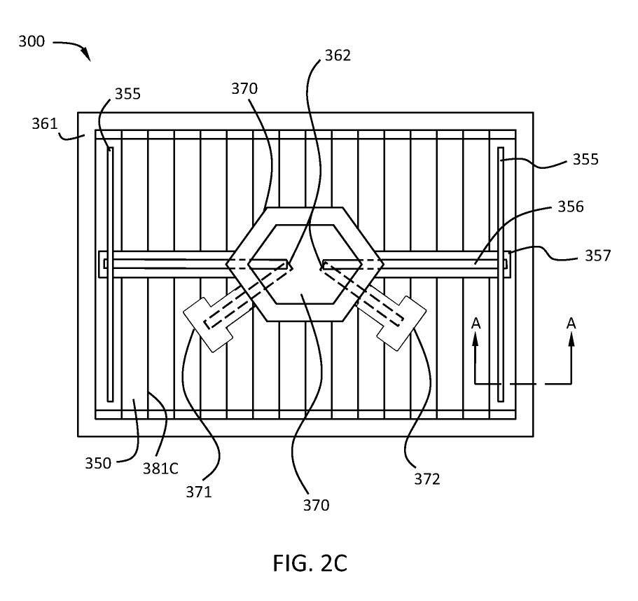

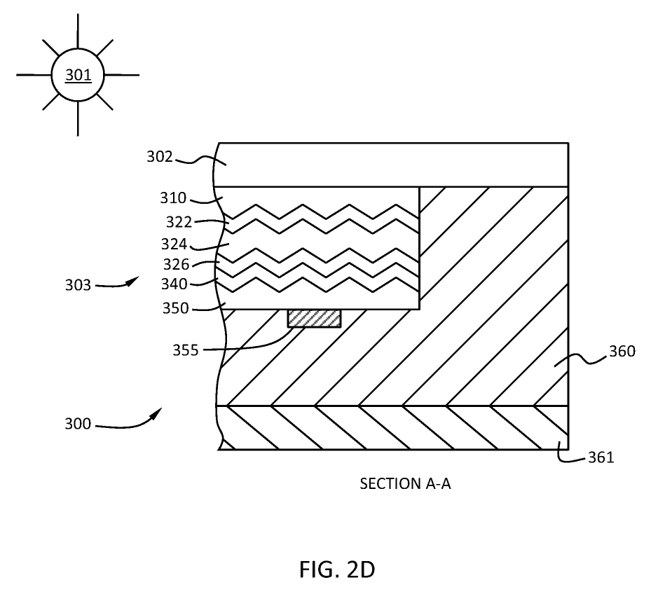

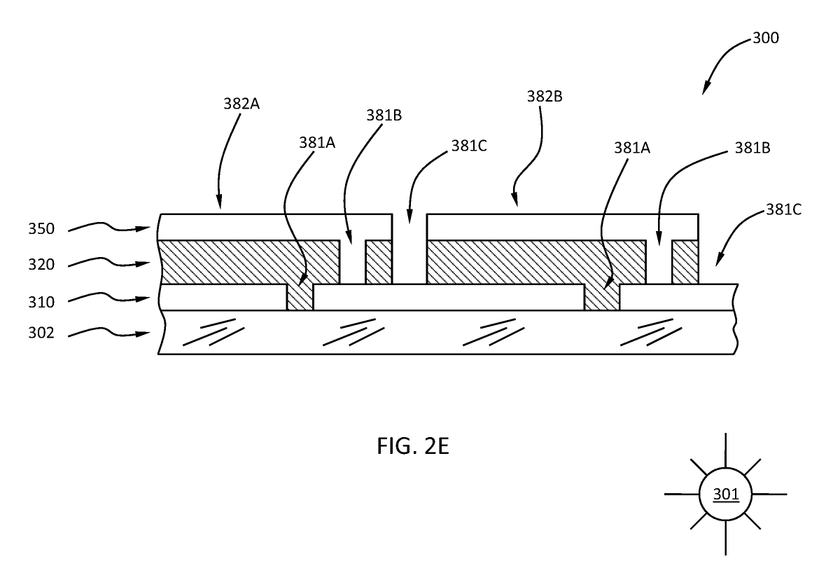

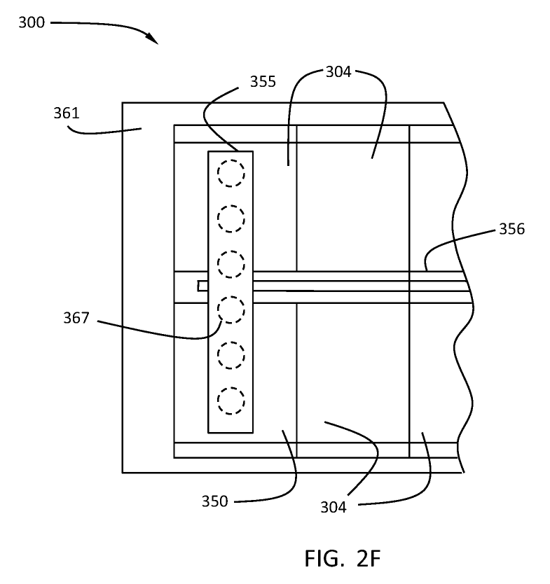

In some embodiments, a bonding wire attach module is used to form the side-buss 355 (FIG. 2C) and cross-buss 356 on the formed back contact region. In this configuration, the side-buss 355 may comprise a conductive material that can be affixed, bonded, and/or fused to the back contact layer 350 in the back contact region to form a robust electrical contact. In one embodiment, the side-buss 355 and cross-buss 356 each comprise a metal strip, such as copper tape, a nickel coated silver ribbon, a silver coated nickel ribbon, a tin coated copper ribbon, a nickel coated copper ribbon, or other conductive material that can carry current delivered by the solar cell module 300 and that can be reliably bonded to the back contact layer 350 in the back contact region. In one embodiment, the metal strip is between about 2 mm and about 10 mm wide and between about 1 mm and about 3 mm thick.

The cross-buss 356, which is electrically connected to the side-buss 355 at junctions, can be electrically isolated from the back contact layer(s) 350 of the solar cell module 300 by use of an insulating material 357, such as an insulating tape. The ends of each of the cross-busses 356 generally have one or more leads 362 that are used to connect the side-buss 355 and the cross-buss 356 to the electrical connections found in a junction box 370, which is used to connect the formed solar cell module 300 to other external electrical components.

Accordingly, one or more embodiments of the invention are directed to methods of making a solar cell module 300. As best shown in the expanded view in FIG. 2F, a plurality of conductive adhesive drops 367 can be applied to the back contact layer 350 of the solar cell module 300. Contacting a side buss 355 to the plurality of conductive adhesive drops 367 creates contact points which can be spot heated to adhere the side buss 355 to the back side 350 of the solar cell module 300.

As best shown in the partial cross-section view of FIG. 2D, in the next steps, step 132 and 134, a bonding material 360 and “back glass” substrate 361 is provided and applied. The back glass substrate 361 is bonded onto the device substrate 303 formed in steps 102-130 above by use of a laminating process (step 134 discussed below). In a detailed embodiment of step 132, a polymeric material is placed between the back glass substrate 361 and the deposited layers on the device substrate 303 to form a hermetic seal to prevent the environment from attacking the solar cell during its life.

In an exemplary process, the device substrate 303, the back glass substrate 361, and the bonding material 360 are transported to a bonding module in which step 134, or lamination steps are performed to bond the backside glass substrate 361 to the device substrate formed in steps 102-130 discussed above. In step 134, a bonding material 360, such as Polyvinyl Butyral (PVB) or Ethylene Vinyl Acetate (EVA), may be sandwiched between the backside glass substrate 361 and the device substrate 303. Heat and pressure are applied to the structure to form a bonded and sealed device using various heating elements and other devices found in the bonding module 234. The device substrate 303, the back glass substrate 361, and the bonding material 360 thus form a composite solar cell structure 304, as shown in FIG. 2D that at least partially encapsulates the active regions of the solar cell device. In some embodiments, at least one hole formed in the back glass substrate 361 remains at least partially uncovered by the bonding material 360 to allow portions of the cross-buss 356 or the side-buss 355 to remain exposed so that electrical connections can be made to these regions of the solar cell structure 304 in future steps (i.e., step 138).

Next the composite solar cell structure 304 is transported to an autoclave module in which step 136, or autoclave steps are performed on the composite solar cell structure 304 to remove trapped gasses in the bonded structure and assure that a good bond is formed during step 134. In step 134, a bonded solar cell structure 304 is inserted in the processing region of the autoclave module where heat and high pressure gases are delivered to reduce the amount of trapped gas and improve the properties of the bond between the device substrate 303, back glass substrate, and bonding material 360. The processes performed in the autoclave are also useful to assure that the stress in the glass and bonding layer (e.g., PVB layer) are more controlled to prevent future failures of the hermetic seal or failure of the glass due to the stress induced during the bonding/lamination process. It may be desirable to heat the device substrate 303, back glass substrate 361, and bonding material 360 to a temperature that causes stress relaxation in one or more of the components in the formed solar cell structure 304.

Additional processing steps 138 may be performed, including but not limited to device testing, additional cleaning, attaching the device to a support structure, unloading modules from processing chambers and shipping.

In detailed embodiments, each of the plurality of adhesive drops 367 on the back contact layer 350 of the solar cell module 300 is spaced in the range of about 1 cm to about 5 cm apart from each other. In other detailed embodiments, the drops are spaced in the range of about 2 cm to about 4 cm apart. In more detailed embodiments, the spots are spaced about 3 cm apart. In some specific embodiments, the spots are spaced greater than 0.5 cm, 1 cm, 1.5 cm, 2 cm, 2.5 cm, 3 cm, 3.5 cm or 4 cm apart.

In some embodiments, the contact points are spot heated for up to about 7 seconds. In detailed embodiments, the contact points are spot heated for up to about 10 second, 9 second, 8 second, 6 seconds, 5 seconds, 4 second, 3 second or 2 seconds.

The contact points of some embodiments are heated to a temperature up to about 300° C. The temperature of detailed embodiments is in the range of about 100° C. to about 400° C. In other detailed embodiments, the temperature range is from about 200° C. top about 350° C.

The contact points of various embodiments can be heated by any suitable spot heating device such as a thermode, ultrasonic, resistive or other electrical heating process. In specific embodiments, the buss is adhered to the solar cell module 300 substantially without the use of flux or solder. In detailed embodiments, the conductive adhesive 367 is substantially the only means used, other than heat, to connect the buss and the solar cell module 300.

In one or more embodiments of the invention, the conductive adhesive comprises silver. The conductive adhesive may be a single component, binary composition or a mixture of several compositions. The conductive adhesive may be pre-mixed, mixed immediately prior to application to the back of the solar module or mixed upon application to the solar module.

The conductive adhesive drops 367 can be applied to the back contact layer 350 of the solar cell module 300 simultaneously or sequentially. In detailed embodiments, the conductive adhesive drops 367 are applied simultaneously using a plurality of dispensing heads. The buss wire 355 can then be placed on the drops and individual thermodes (or similar devices) can spot heat directly over the buss wire where the plurality of drops 367 where dispersed.

Further embodiments of the invention are directed to methods of making a solar cell module 300. The methods comprise forming a plurality of solar cells 304. This can be done as described above, or according to other methods known to those skilled in the art. A buss 355 is applied to the plurality of solar cells 304, the buss 355 connecting a row of solar cells 304. A buss 355 is applied to the plurality of solar cells 304, the buss 355 being adhered to the plurality of solar cells 304 by a plurality of conducting adhesive drops 367. The buss 355 connecting the row of solar cells 304 and the buss 355 being adhered by the conductive adhesive drops 367 can be the same buss 355, or different busses. For example, with reference to FIG. 2F, the conductive adhesive drops 367 may be used on one or more of a side buss 355 or a cross-buss 356.

Additional embodiments of the invention are directed to solar cell modules 300. The modules 300 comprise at least two solar cells 304 and a buss 356 connecting the at least two solar cells 304. The buss 356 is adhered to the at least two solar cells 304 by a plurality of conductive adhesive drops 367.

In detailed embodiments, the solar cell 304 comprises a thin film solar panel and the buss comprises a side buss 356 to connect at least two cells 304 for current capture. In other detailed embodiments the solar cell 304 comprises a silicon solar cell and the buss 355 is adhered to at least two solar cells 304. As used herein, the term “buss” refers to an electrical connection between solar cells, including solar modules made from interconnected silicon cells or solar modules that are made from interconnected thin film solar cells. As is understood by the skilled artisan, silicon solar cells are typically connected by a buss wire. For solar modules or solar panels made from thin film solar cells, the end solar cells are connected by a side buss connecting the end cells for current capture. Thus, the term “buss” is broadly intended to include a connection between solar cells, whether the connection is between two silicon solar cells, or between two thin film solar cells.

The conductive adhesive drops of some embodiments are curable when heated up to a maximum of about 300° C. for less than about 7 seconds. In other detailed embodiments, the conductive adhesive is curable when heated up to a maximum of 150°, 200°, 250°, 300°, 350° or 400° C.

In specific embodiments, no flux or solder is used to connect the side buss to the solar cells. The conductive adhesive of detailed embodiments comprises silver. According to detailed embodiments, the conductive adhesive drops have a diameter in the range of about 1 mm to about 5 mm. In other detailed embodiments, the drops have a diameter in the range of about 2 mm to about 4 mm. In further detailed embodiments, the diameter of the conductive adhesive drops is greater than about 1 mm, 2 mm, 3 mm, 4 mm or 5 mm.

Examples of a solar cell modules 300 that can be formed using the process sequences illustrated in FIG. 1 and previously described are illustrated in FIGS. 2A-2F. FIG. 2A is a simplified schematic diagram of a single junction amorphous silicon solar cell 304 that can be formed using the previously described process.

As shown in FIG. 2A, the single junction amorphous silicon solar cell 304 is oriented toward a light source or solar radiation 301. The solar cell 304 generally comprises a substrate 302, such as a glass substrate, polymer substrate, metal substrate, or other suitable substrate, with thin films formed thereover. In one embodiment, the substrate 302 is a glass substrate that is about 2200 mm×2600 mm×3 mm in size. The solar cell 304 further comprises a first transparent conducting oxide (TCO) layer 310 (e.g., zinc oxide (ZnO), tin oxide (SnO)) formed over the substrate 302, a first p-i-n junction 320 formed over the first TCO layer 310, a second TCO layer 340 formed over the first p-i-n junction 320, and a back contact layer 350 formed over the second TCO layer 340. To improve light absorption by enhancing light trapping, the substrate and/or one or more of the thin films formed thereover may be optionally textured by wet, plasma, ion, and/or mechanical processes. For example, in the embodiment shown in FIG. 2A, the first TCO layer 310 is textured, and the subsequent thin films deposited thereover generally follow the topography of the surface below it.

In one configuration, the first p-i-n junction 320 may comprise a p-type amorphous silicon layer 322, an intrinsic type amorphous silicon layer 324 formed over the p-type amorphous silicon layer 322, and an n-type microcrystalline silicon layer 326 formed over the intrinsic type amorphous silicon layer 324. In one example, the p-type amorphous silicon layer 322 may be formed to a thickness between about 60 Å and about 300 Å, the intrinsic type amorphous silicon layer 324 may be formed to a thickness between about 1,500 Å and about 3,500 Å, and the n-type microcrystalline silicon layer 326 may be formed to a thickness between about 100 Å and about 400 Å. The back contact layer 350 may include, but is not limited to, a material selected from the group consisting of Al, Ag, Ti, Cr, Au, Cu, Pt, Ni, Mo, conductive carbon, alloys thereof, and combinations thereof.

FIG. 2B is a schematic diagram of an embodiment of a solar cell 304, which is a multi-junction solar cell that is oriented toward the light or solar radiation 301. The solar cell 304 comprises a substrate 302, such as a glass substrate, polymer substrate, metal substrate, or other suitable substrate, with thin films formed thereover. The solar cell 304 may further comprise a first transparent conducting oxide (TCO) layer 310 formed over the substrate 302, a first p-i-n junction 320 formed over the first TCO layer 310, a second p-i-n junction 330 formed over the first p-i-n junction 320, a second TCO layer 340 formed over the second p-i-n junction 330, and a back contact layer 350 formed over the second TCO layer 340.

In the embodiment shown in FIG. 2B, the first TCO layer 310 is textured, and the subsequent thin films deposited thereover generally follow the topography of the surface below it. The first p-i-n junction 320 may comprise a p-type amorphous silicon layer 322, an intrinsic type amorphous silicon layer 324 formed over the p-type amorphous silicon layer 322, and an n-type microcrystalline silicon layer 326 formed over the intrinsic type amorphous silicon layer 324. In one example, the p-type amorphous silicon layer 322 may be formed to a thickness between about 60 Å and about 300 Å, the intrinsic type amorphous silicon layer 324 may be formed to a thickness between about 1,500 Å and about 3,500 Å, and the n-type microcrystalline silicon layer 326 may be formed to a thickness between about 100 Å and about 400 Å.

The second p-i-n junction 330 may comprise a p-type microcrystalline silicon layer 332, an intrinsic type microcrystalline silicon layer 334 formed over the p-type microcrystalline silicon layer 332, and an n-type amorphous silicon layer 336 formed over the intrinsic type microcrystalline silicon layer 334. In one example, the p-type microcrystalline silicon layer 332 may be formed to a thickness between about 100 Å and about 400 Å, the intrinsic type microcrystalline silicon layer 334 may be formed to a thickness between about 10,000 Å and about 30,000 Å, and the n-type amorphous silicon layer 336 may be formed to a thickness between about 100 Å and about 500 Å. The back contact layer 350 may include, but is not limited to a material selected from the group consisting of Al, Ag, Ti, Cr, Au, Cu, Pt, Ni, Mo, conductive carbon, alloys thereof, and combinations thereof.

FIG. 2C is a plan view that schematically illustrates an example of the rear surface of a formed solar cell module 300 produced by the previously described procedure. FIG. 2D is a side cross-sectional view of a portion of the solar cell module 300 illustrated in FIG. 2C (see section A-A). While FIG. 2D illustrates the cross-section of a single junction cell similar to the configuration described in FIG. 2A, this is not intended to be limiting as to the scope of the invention described herein. FIG. 2F is an expanded view of a portion of the plan view shown in FIG. 2C.

As shown in FIGS. 2C, 2D and 2F, the solar cell module 300 may contain a substrate 302, the solar cell device elements (e.g., reference numerals 310-350), one or more internal electrical connections (e.g., side-buss 355, cross-buss 356), a layer of bonding material 360, a back glass substrate 361, and a junction box 370. The junction box 370 may generally contain two junction box terminals 371, 372 that are electrically connected to leads 362 of the solar cell module 300 through the side-buss 355 and the cross-buss 356, which are in electrical communication with the back contact layer 350 and active regions of the solar cell module 300. To avoid confusion relating to the actions specifically performed on the substrates 302 in the discussion above, a substrate 302 having one or more of the deposited layers (e.g., reference numerals 310-350) and/or one or more internal electrical connections (e.g., side-buss 355, cross-buss 356) disposed thereon is generally referred to as a device substrate 303. Similarly, a device substrate 303 that has been bonded to a back glass substrate 361 using a bonding material 360 is referred to as a composite solar cell module 304. FIG. 2F shows the conductive adhesive drops 367, in dotted-lines to indicate that the drops 367 are beneath the side-buss 355. The conductive adhesive drops 367 can be used to connect one or both of the side-buss 355 and the cross buss 356.

FIG. 2E is a schematic cross-section of a solar cell module 300 illustrating various scribed regions used to form the individual cells 382A-382B within the solar cell module 300. As illustrated in FIG. 2E, the solar cell module 300 includes a transparent substrate 302, a first TCO layer 310, a first p-i-n junction 320, and a back contact layer 350. Three laser scribing steps may be performed to produce trenches 381A, 381B, and 381C, which are generally required to form a high efficiency solar cell device. Although formed together on the substrate 302, the individual cells 382A and 382B are isolated from each other by the insulating trench 381C formed in the back contact layer 350 and the first p-i-n junction 320. In addition, the trench 381B is formed in the first p-i-n junction 320 so that the back contact layer 350 is in electrical contact with the first TCO layer 310. In one embodiment, the insulating trench 381A is formed by the laser scribe removal of a portion of the first TCO layer 310 prior to the deposition of the first p-i-n junction 320 and the back contact layer 350. Similarly, in one embodiment, the trench 381B is formed in the first p-i-n junction 320 by the laser scribe removal of a portion of the first p-i-n junction 320 prior to the deposition of the back contact layer 350. While a single junction type solar cell is illustrated in FIG. 2E this configuration is not intended to be limiting to the scope of the invention described herein.

Although the invention herein has been described with reference to particular embodiments, it is to be understood that these embodiments are merely illustrative of the principles and applications of the present invention. It will be apparent to those skilled in the art that various modifications and variations can be made to the method of the present invention without departing from the spirit and scope of the invention. Thus, it is intended that the present invention include modifications and variations that are within the scope of the appended claims and their equivalents.

What is claimed is:

1. A solar cell module comprising:
at least two solar cells; and
a buss connecting the at least two solar cells, the buss adhered to the at least two solar cells by a plurality of conductive adhesive drops.

2. The solar cell module of claim 1, wherein the solar cell comprises a thin film solar panel and the buss comprises a side buss to connect at least two cells for current capture.

3. The solar cell module of claim 1, wherein the solar cell comprises a silicon solar cell and the buss is adhered to at least two solar cells.

4. The solar cell module of claim 1, wherein the conductive adhesive drops are curable when heated up to a maximum of 300° C. for less than about 7 seconds.

5. The solar cell module of claim 1, wherein substantially no flux or solder is used to connect the side buss to the solar cells.

6. The solar cell module of claim 1, wherein the plurality of conductive adhesive drops are spaced in the range of about 2 cm to about 4 cm apart.

7. The solar cell module of claim 1, wherein the plurality of conductive adhesive drops are spaced about 3 cm apart.

8. The solar cell module of claim 1, wherein the conductive adhesive comprises silver.

9. The solar cell module of claim 1, wherein the conductive adhesive comprises a mixture.

10. The solar cell module of claim 1, wherein the conductive adhesive drops have a diameter in the range of about 1 mm to about 5 mm.

11. A method of making a solar cell module, comprising:
applying a plurality of conductive adhesive drops to a back contact layer of the solar cell module;
creating contact points by contacting a side buss to the plurality of conductive adhesive drops; and
spot heating the contact points to adhere the side buss to the back side of the solar cell module.

12. The method of claim 11, wherein the plurality of adhesive drops are spaced in the range of about 2 cm to about 4 cm apart.

13. The method of claim 11, wherein the contact points are spot heated for up to about 7 seconds.

14. The method of claim 13, wherein the contact points are heated to a temperature up to about 300° C.

15. The method of claim 11, wherein the contact points are heated by a thermode, ultrasonic, resistive or other electrical heating process.

16. The method of claim 11, wherein the conductive adhesive comprises silver.

17. A method of making a solar cell module, comprising:
forming a plurality of solar cells;
applying a buss to the plurality of solar cells, the buss connecting a row of solar cells; and
applying a buss to the plurality of solar cells, the buss adhered to the plurality of solar cells by a plurality of conductive adhesive drops.

18. The method of claim 17, wherein the conductive adhesive is substantially cured when heated up to 300° C. for up to about 7 seconds.

19. The method of claim 17, wherein the buss is adhered to the plurality of solar cells substantially without flux or solder.
